(19) United States
(12) Patent Application Publication
(10) Pub. No.: US 2012/0001263 A1
(43) Pub. Date: Jan. 5, 2012

(54) Replacement Gate Approach for High-K Metal Gate Stacks Based on a Non-Conformal Interlayer Dielectric

(75) Inventors: Ralf Richter, Dresden (DE); Kai Frohberg, Niederau (DE)

(73) Assignee: GLOBALFOUNDRIES INC., Grand Cayman (KY)

(21) Appl. No.: 12/970,261

(22) Filed: Dec. 16, 2010

(30) Foreign Application Priority Data
Jun. 30, 2010 (DE) 10 2010 030 756.4

(51) Int. Cl. H01L 29/78; H01L 21/28

(52) U.S. Cl. 257/368; 438/586; 257/E21.19; 257/E29.264

(57) ABSTRACT

In replacement gate approaches for forming sophisticated high-k metal gate electrode structures in a late manufacturing stage, the exposing of the placeholder material may be accomplished on the basis of a substantially uniform interlayer dielectric material, for instance in the form of a silicon nitride material, which may have a similar removal rate compared to the dielectric cap material, the spacer elements and the like of the gate electrode structures. Consequently, a pronounced degree of recessing of the interlayer dielectric material may be avoided, thereby reducing the risk of forming metal residues upon removing any excess material of the gate metal.

### BACKGROUND OF THE INVENTION

1. Field of the Invention

Generally, the present disclosure relates to sophisticated integrated circuits including transistor elements comprising gate structures formed on the basis of a high-k gate dielectric material and a metal-containing electrode material, wherein at least the metal-containing electrode material is provided in a late manufacturing stage.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, CMOS technology is one of the most promising approaches due to the superior characteristics in view of operating speed and/or power consumption and/or cost efficiency. During the fabrication of complex integrated circuits using, for instance, CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, on the distance between the source and drain regions, which is also referred to as channel length. Hence, the conductivity of the channel region substantially affects the performance of MOS transistors. Thus, the scaling of the channel length, and associated therewith the reduction of channel resistivity, has been a dominant design criterion for accomplishing an increase in the operating speed of the integrated circuits.

Presently, the vast majority of integrated circuits are based on silicon due to substantially unlimited availability, the well-understood characteristics of silicon and related materials and processes and the experience gathered during the last 50 years. Therefore, silicon will likely remain the material of choice in the near future for circuits designed for mass production. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a base material of the gate insulation layer that separates the gate electrode, frequently comprised of polysilicon, at the interface between the gate dielectric and the electrode material, from the silicon channel region. In steadily improving device performance of field effect transistors, the length of the channel region has been continuously reduced to improve switching speed and drive current capability. Since the transistor performance in terms of switching speed and drive current is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be ensured. It turns out that decreasing the channel length requires an increased capacitive coupling to avoid the so-called short channel behavior during transistor operation. Thus, the thickness of the silicon dioxide based layer has to be correspondingly reduced to provide the required capacitance between the gate and the channel region. For example, a channel length of approximately 0.08 μm may require a gate dielectric made on the basis of silicon dioxide as thin as approximately 1.2 nm. Although, generally, usage of high speed transistor elements having an extremely short channel may be substantially restricted to high speed signal paths, whereas transistor elements with a longer channel may be used for less critical signal paths, such as storage transistor elements, the relatively high leakage current caused by direct tunneling of charge carriers through an ultra-thin silicon dioxide gate insulation layer may reach values for an oxide thickness in the range of 1-2 nm that may not be compatible with thermal design power requirements for performance driven circuits.

Therefore, replacing silicon dioxide based dielectrics as the material for gate insulation layers has been considered, particularly for extremely thin silicon dioxide based gate layers. Possible alternative materials include materials that exhibit a significantly higher permittivity so that a physically greater thickness of a correspondingly formed gate insulation layer provides a capacitive coupling that would be obtained by an extremely thin silicon dioxide layer.

Additionally, transistor performance may be increased by providing an appropriate conductive material for the gate electrode to replace the usually used polysilicon material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides enhanced channel control, while additionally maintaining leakage currents at an acceptable level. On the other hand, the non-polysilicon material, such as titanium nitride and the like, in combination with other metals, may be formed so as to connect to the high-k dielectric material, thereby substantially avoiding the presence of a depletion zone. Since the threshold voltage of the transistors, which represents the voltage at which a conductive channel forms in the channel region, is significantly determined by the work function of the metal-containing gate material, an appropriate adjustment of the effective work function with respect to the conductivity type of the transistor under consideration has to be guaranteed.

Providing different metal species for adjusting the work function of the gate electrode structures for P-channel transistors and N-channel transistors at an early manufacturing stage may, however, be associated with a plurality of difficulties, which may stem from the fact that a complex patterning sequence may be required during the formation of the sophisticated high-k metal gate stack, which may result in a significant variability of the resulting work function and thus threshold voltage of the completed transistor structures. For instance, during a corresponding manufacturing sequence, the high-k material may be exposed to oxygen, which may result in an increase of layer thickness and thus a reduction of the capacitive coupling. Moreover, a shift of the work function may be observed when forming appropriate work function metals in an early manufacturing stage, which is believed to be caused by a moderately high oxygen affinity of the metal species, in particular during high temperature processes which may typically be required for completing the transistor structures, for instance, for forming drain and source regions and the like.

For this reason, in some approaches, the initial gate electrode stack may be provided with a high degree of compatibility with conventional polysilicon-based process strategies and the actual electrode metal, possibly in combination with a high-k dielectric material, and the final adjustment of the work function of the transistors may be accomplished in a very advanced manufacturing stage, i.e., after completing the basic transistor structure. In a corresponding replacement gate approach, the high-k dielectric material, if provided in this stage, may be covered by an appropriate metal-containing material, such as titanium nitride and the like, followed by a standard polysilicon or amorphous silicon material, which may then be patterned on the basis of well-established advanced lithography and etch techniques. Consequently, during the process sequence for patterning the gate electrode structure, the sensitive high-k dielectric material may be protected by the metal-containing material, possibly in combination with sophisticated sidewall spacer structures, thereby substantially avoiding any undue material modification during the further processing. After patterning the gate electrode structure, conventional and well-established process techniques for forming the drain and source regions having the desired complex dopant profile are typically performed. After any high temperature processes, the further processing may be continued, for instance, by forming a metal silicide, followed by the deposition of an interlayer dielectric material, such as silicon nitride in combination with silicon dioxide and the like. In this manufacturing stage, a top surface of the gate electrode structures embedded in the interlayer dielectric material has to be exposed, which is accomplished in many approaches by chemical mechanical polishing (CMP). The polysilicon material exposed during the CMP process is then removed and thereafter an appropriate masking regime may be applied in order to selectively fill in an appropriate metal for any type of transistors.

Although, in general, this approach provides advantages in view of reducing process-related non-uniformities with respect to the threshold voltages of the transistors, since the sensitive metal species for adjusting the work function of the gate electrode structures may be provided after any high temperature processes, the complex process sequence for exposing and replacing the placeholder material may result in a pronounced yield loss, as will be explained in more detail with reference to FIGS. 1a-1d.

FIG. 1a schematically illustrates a cross-sectional view of a semiconductor device 100 in an advanced manufacturing stage, i.e., after completing the basic configuration of transistors 150A, 150B. As illustrated, the semiconductor device 100 comprises a substrate 101, which typically represents a silicon-based carrier material, above which is formed a semiconductor layer 102, for instance a silicon-based crystalline material. Furthermore, an active region 102A is provided in the semiconductor layer 102, for instance on the basis of any appropriate isolation structure (not shown), such as a shallow trench isolation. In the example shown in FIG. 1a, the transistors 150A, 150B may thus be formed in and above the active region 102A, thereby, for instance, representing closely spaced transistors of the same conductivity type. Hence, drain and source regions 152 and corresponding channel regions 153 may be provided in the active region 102A, possibly in combination with contact areas 154, which may represent a portion of the drain and source regions 152 or, as shown in FIG. 1a, may be provided in the form of a metal silicide material.

The transistors 150A, 150B comprise gate electrode structures 110A, 110B, respectively, which may have a critical dimension, i.e., a gate length of 50 nm and significantly less in sophisticated semiconductor devices. It should be appreciated that the gate length of the structures 110A, 110B is to be understood in FIG. 1 a as the horizontal extension of a placeholder material 112, which may be provided in the form of a polysilicon material, and which is separated from the channel region 153 by a gate dielectric material 111, which may comprise a high-k dielectric material, possibly in combination with a conventional dielectric material, depending on the overall process strategy. In other examples, the dielectric material 111 may represent any appropriate stack of layers, such as layers 111A, 111B in compliance with the further processing. Furthermore, typically, a dielectric cap layer 113 is provided in the gate electrode structures, for instance, in the form of a silicon nitride material, which in combination with a sidewall spacer element 114, for instance comprised of silicon nitride, may be used for appropriately encapsulating the gate electrode structures 110A, 110B during certain processes, for instance, for incorporating a strain-inducing embedded semiconductor material in the active region 102A (not shown). In other cases, the dielectric cap layer 113 may typically be used as a mask material during a complex patterning process for forming the gate electrode structures 110A, 110B on the basis of the required critical dimensions. Furthermore, a further spacer structure 115 may typically be provided in the gate electrode structures 110A, 110B in order to define an appropriate lateral offset and thus an appropriate profile of the drain and source regions 152 and possibly a desired lateral offset of the metal silicide regions 154, if provided in this manufacturing stage. In the manufacturing stage shown, a dielectric material of a contact level 160 is provided, wherein usually a first dielectric layer 161, such as a silicon nitride material and the like, is provided in combination with a silicon dioxide material 162, which is a well-established interlayer dielectric material for passivating circuit elements and acts as an interface with respect to a metallization system to be formed above the contact level 160. The dielectric layer 161, which may differ in material composition from the material 162 in order to act as an etch stop material during the further processing, may frequently be provided with a high internal stress level in order to enhance performance of the transistors 150A, 150B.

The semiconductor device 100 as illustrated in FIG. 1 a may be formed on the basis of any appropriate process strategy. For example, the active region 102A is formed by defining the lateral position and size thereof upon forming an appropriate isolation structure using well-established process techniques. Prior to or after forming the isolation structure, an appropriate dopant species is incorporated in order to adjust the basic transistor characteristics for the devices 150A, 150B. Next, a gate dielectric material, such as the layer 111 or layer system, is formed, for instance, by oxidation and/or deposition and the like, wherein, as previously discussed, high-k dielectric materials may also be provided, possibly in combination with a metal-containing cap material (not shown), while in other cases any appropriate layer system may be provided while any high-k dielectric materials may be incorporated into the gate electrode structures 110A, 110B in a later manufacturing stage. Next, the placeholder material 112 and the dielectric cap material 113, possibly in combination with any further materials, such as hard mask materials, anti-reflective coating (ARC) materials and the like may be provided and may be patterned by using sophisticated lithography and etch techniques. Thereafter, the spacer element 114 is formed, if required, for instance by using chemical vapor deposition (CVD) techniques for forming a silicon nitride material, followed by any further process strategies, for instance incorporating a strain-inducing semiconductor alloy and the like, as previously discussed. Thereafter, the drain and source regions 152 in combination with the spacer structure 115 may be formed by using well-established implantation techniques in combination with an appropriate masking scheme. It should be appreciated that the spacer structure 115 may typically comprise one or more spacer elements formed of silicon nitride, possibly in combination with a silicon dioxide etch stop liner (not shown). After any high temperature anneal processes, the metal silicide 154 may be formed, if required in this manufacturing stage, which may be accomplished by using well-established process strategies. Next, the dielectric material 161 may be deposited by using plasma enhanced CVD techniques in which process parameters, such as flow rate, process temperature, pressure and the like, are appropriately adjusted so as to obtain a substantially conformal deposition behavior, so that the thickness of the dielectric layer 161 is substantially uniform, i.e., the thickness may vary by approximately ten percent or less. For this purpose, a plurality of well-established process recipes are available, wherein, as discussed above, in some cases, a high internal stress level may be generated during the deposition of the layer 161. Next, the silicon dioxide material 162 is deposited, for instance, by sub-atmospheric CVD, high density plasma CVD and the like, wherein typically a non-conformal deposition behavior may result in a reliable filling of the space between the gate electrode structures 110A, 110B, even if sophisticated device geometries are considered. Due to the pronounced surface topography after the deposition of the conformal silicon nitride layer 161, a certain topography may also be generated after the deposition of the silicon dioxide material 162.

FIG. 1b schematically illustrates the device 100 in a further advanced manufacturing stage. As illustrated, a CMP process is applied so as to first planarize the surface topography and subsequently further remove the materials above the gate electrode structures 110A, 110B in order to finally expose a top surface 112S of the placeholder material 112. Consequently, during the CMP process 105, at least two different materials, such as the silicon dioxide material 162 and the silicon nitride material 161, have to be processed commonly in a phase when the layer 161 is increasingly exposed during the process 105. Thereafter, the process 105 may increasingly remove the material 161 above the gate electrode structures 110A, 110B, while also polishing the silicon dioxide material 162. In a further advanced stage of the process 105, the dielectric cap layer 113 and also the spacer structures 114, 115 are exposed and also material of these components has to be removed during the process 105 so as to finally expose the placeholder material 112. Consequently, in this final phase of the polishing process 105, a further material, i.e., the polysilicon material 112, is present and thus additionally contributes to the overall complex process conditions during the process 105. That is, it is extremely difficult to adjust the process conditions during the removal process so as to obtain precisely the same removal rates for the silicon dioxide material 162 and the silicon nitride material 161. For this purpose, the process parameters such as down force, relative speed and in particular the composition of the slurry material may have to be taken into consideration and be appropriately selected in order to minimize a difference in removal rate. Upon removing the dielectric cap layer 113, the situation may become even more complex since frequently the cap layers of different transistors may have a different thickness due to a different process history, thereby typically requiring a pronounced overpolish time so as to reliably expose the placeholder material 112 for any type of transistors across the entire substrate 101. In this phase, increasingly, a third material, i.e., the polysilicon material 112, may be exposed and may thus also need to be polished with substantially the same removal rate or with an increased removal rate compared to the silicon nitride material of the cap layer 113 and of the spacer structures 114, 115 and the layer 161 and the silicon dioxide material 162. A complete removal of any silicon nitride or silicon dioxide residues may be extremely important for the subsequent processing, i.e., for the replacing of the material 112 by electrode metals, a high-k dielectric material and the like. Hence, due to the complexity of the removal process 105, frequently, a certain mismatch of the removal rates may occur, wherein usually the silicon dioxide material 162 may be removed more rapidly compared to the silicon nitride material 161, thereby forming a certain degree of “dishing” or recessing, as indicated by 162D.

After the exposure of the surface areas 112S, the further processing may be continued by applying highly selective wet chemical etch techniques in order to remove the polysilicon material 112 and possibly the layer 111 or at least a portion thereof, depending on the overall process and device requirements. Thereafter, appropriate metal-containing materials may be filled into the gate electrode structures 110A, 110B, wherein also a high-k dielectric material may be applied, if required. After the deposition of the complex material system, a highly conductive electrode metal, such as aluminum, is typically provided and thereafter any excess material is removed, for instance by CMP. Consequently, due to the pronounced recessing 162D, in particular in the silicon dioxide material 162, the corresponding metal-containing electrode materials may also be formed in these recesses 162D, wherein a portion of these materials may be preserved, even after a significant overpolish time upon removing any excess materials.

FIG. 1c schematically illustrates the device 100 in this manufacturing stage. As shown, the gate electrode structures 110A, 110B may comprise a complex material system 116 including appropriate metal species and highly conductive electrode metals, possibly in combination with a high-k dielectric material, wherein certain residues 116R may remain on or within the silicon dioxide material 162, which may thus result in increased leakage currents or even short circuits during the further processing, i.e., forming contact elements so as to connect to the active region 102A.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which the removal process for exposing a placeholder material of sophisticated gate electrode structures may be enhanced by providing superior conditions, for instance by avoiding the presence of the different materials during the removal process. To this end, the interlayer dielectric material may be substantially provided as a uniform material having the same material composition above and adjacent to the gate electrode structures, except for a very thin etch stop material, which may be provided, in some illustrative embodiments, so that the removal process, such as a CMP process, may be performed with superior process uniformity. In some aspects disclosed herein, the interlayer dielectric material may be provided in the form of a material having substantially the same basic composition compared to the spacer structure and the dielectric cap material, if provided, thereby further enhancing the overall uniformity of the removal process. For example, in some illustrative embodiments disclosed herein, the interlayer dielectric material may be provided in the form of a silicon nitride-containing material, which may be provided on the basis of a non-conformal deposition process in order to reliably fill the space even between closely spaced gate electrode structures.

One illustrative method disclosed herein comprises forming a dielectric layer above a gate electrode structure of a transistor, wherein the gate electrode structure comprises a placeholder material and a dielectric cap layer formed above the placeholder material. The dielectric cap layer and the dielectric layer comprise a common dielectric base material. The method further comprises removing the dielectric cap layer and a portion of the dielectric layer to expose a surface of the placeholder material. Additionally, the method comprises replacing the placeholder material at least with a metal-containing electrode material.

A further illustrative method disclosed herein comprises forming a silicon nitride-containing dielectric material above and laterally adjacent to a gate electrode structure of a transistor by performing a non-conformal deposition process, wherein the gate electrode structure comprises a placeholder material. Furthermore, the method comprises forming an exposed top surface of the placeholder material by removing a portion of the dielectric material. Additionally, the method comprises replacing the placeholder material with at least a metal-containing electrode material.

One illustrative semiconductor device disclosed herein comprises a first high-k metal gate electrode structure and a second high-k metal gate electrode structure comprising a metal gate electrode material. The semiconductor device further comprises an interlayer dielectric material formed laterally between the first and second high-k metal gate electrode structures and having a substantially uniform thickness and a substantially constant height level between spacer structures of the first and second gate electrode structures.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of a semiconductor device in an advanced manufacturing stage upon replacing a polysilicon material with metal-containing electrode materials according to a replacement gate approach performed on the basis of conventional process strategies;

FIGS. 2a-2d schematically illustrate cross-sectional views of a semiconductor device during various manufacturing stages in which a replacement gate approach may be applied on the basis of a substantially uniform interlayer dielectric material so as to significantly reduce process complexity during a removal process for exposing the placeholder material, according to illustrative embodiments; and

FIG. 2e schematically illustrates the semiconductor device according to further illustrative embodiments in which a thin etch stop material may be provided in combination with a silicon nitride-based interlayer dielectric material.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides manufacturing techniques and semiconductor devices in which a placeholder material of gate electrode structures may be exposed in a late manufacturing stage by reducing the complexity of a corresponding removal process, such as a chemical mechanical planarization process. To this end, the complexity of the material system of the interlayer dielectric material may be reduced in that a substantially uniform material composition may be provided above and adjacent to the gate electrode structures, wherein, in some illustrative embodiments, only a very thin etch stop material may be provided, for instance in the form of any appropriate etch stop material having a thickness of approximately 10 nm or less. In some embodiments disclosed herein, the interlayer dielectric material may be provided so as to be comprised of a dielectric base material, which may also be used in other components, such as a dielectric cap material formed on the place-holder material, spacer elements and the like. Consequently, upon planarizing and removing a significant portion of the interlayer dielectric material, the components increasingly exposed during the removal process may have a similar removal rate, except for very thin etch stop liners and the like, thereby avoiding a pronounced dishing of the interlayer dielectric material, in particular between closely spaced gate electrode structures. In some illustrative embodiments, the interlayer dielectric material may be provided in the form of a silicon nitride material, which may have basically the same composition as the material as used in spacer elements and dielectric cap materials, thereby providing the desired reduction in complexity of the material system to be planarized and partially removed upon exposing the placeholder material. The interlayer dielectric material may be formed on the basis of appropriate non-conformal deposition techniques in which the process parameters may be appropriately selected such that a superior bottom-to-top fill behavior is achieved, as is well-established for a plurality of dielectric materials, such as silicon dioxide, silicon nitride and the like. Consequently, based on the non-conformal deposition behavior, a reliable and void-free filling of the spacing between sophisticated gate electrode structures may be achieved.

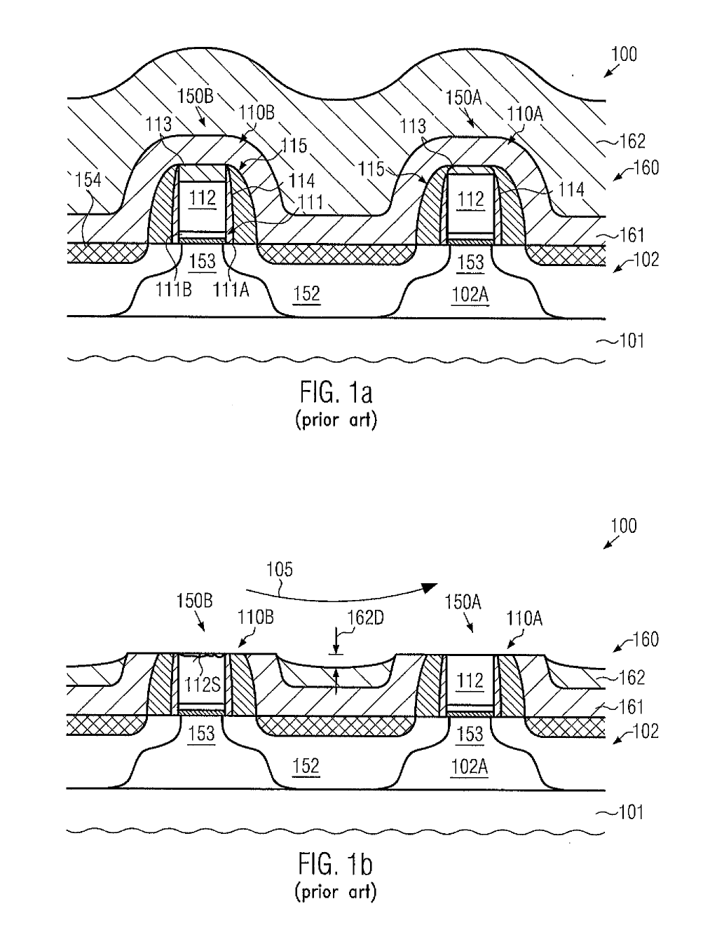

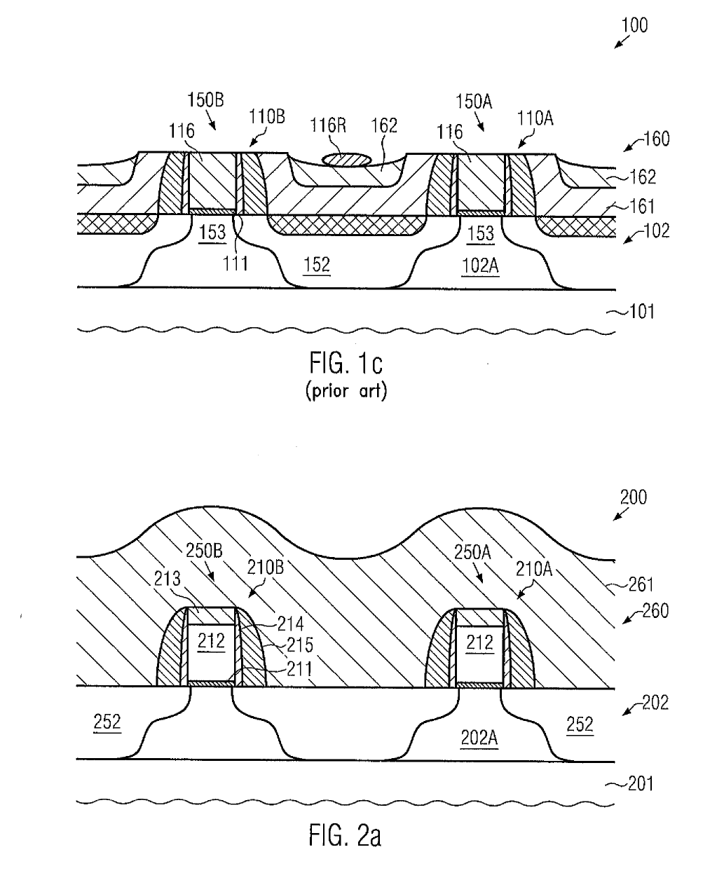

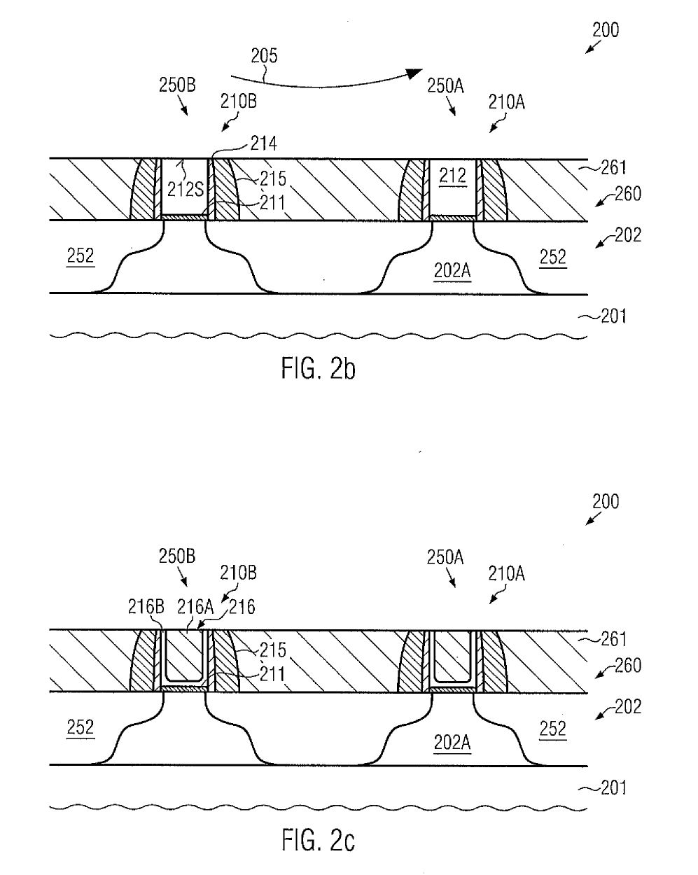

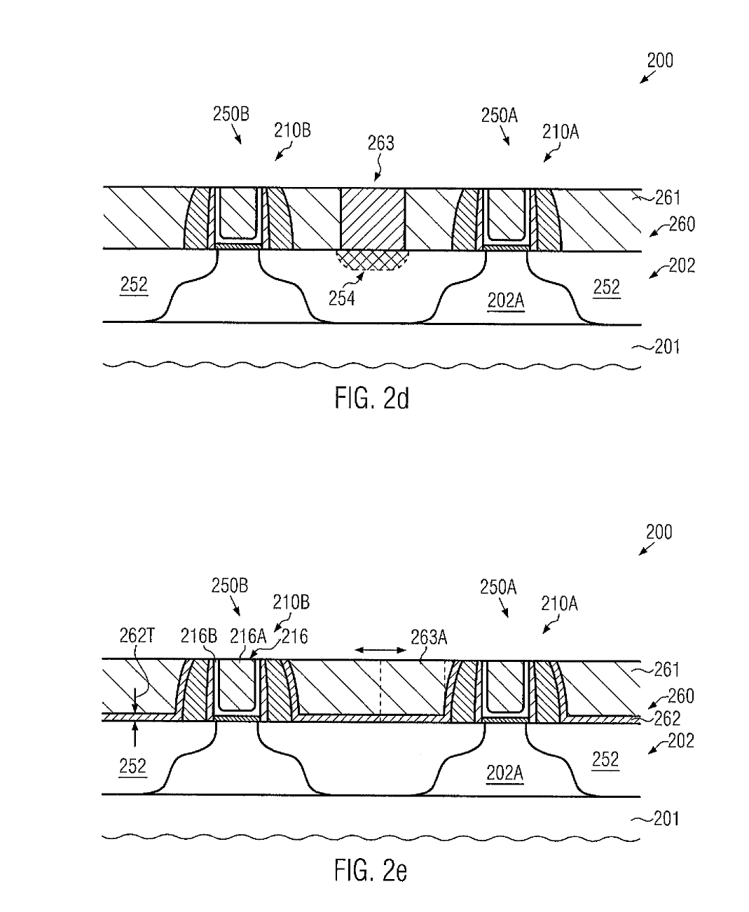

With reference to FIGS. 2a-2e, further illustrative embodiments will now be described in more detail, wherein reference may also be made to FIGS. 1a-1c, if required.

FIG. 2a schematically illustrates a cross-sectional view of a semiconductor device 200 in an advanced manufacturing stage. As illustrated, the device 200 may comprise a semiconductor layer 202 formed above a substrate 201, wherein, if a silicon-on-insulator (SOI) device may be considered, a buried insulating material (not shown) may be formed between the substrate 201 and the semiconductor layer 202. Furthermore, a plurality of active regions are typically formed in the semiconductor layer 202, for instance by providing appropriately dimensioned isolation structures (not shown), wherein, for convenience, a single active region 202A may be illustrated, in and above which closely spaced transistors 250A, 250B may be provided. It should be appreciated, however, that other active regions may be formed in the layer 202 in which a single transistor or more than two transistors may be provided. In the manufacturing stage shown, drain and source regions 252 may be formed in the active region 202A in accordance with device requirements for the transistors 250A, 250B. The drain and source regions 252 may comprise, in this manufacturing stage, metal silicide regions (not shown) as is previously discussed with reference to the semiconductor device 100, while, in other embodiments, any such contact regions of superior conductivity may be provided in a later manufacturing stage. Moreover, a gate electrode structure 210A and a gate electrode structure 210B may be formed on the active region 202A and may comprise a dielectric layer 211, which may comprise two or more different dielectric materials, as is also previously discussed, while, in other cases, the dielectric material 211 may represent one or more conventional dielectric materials, while, in still other cases, any high-k dielectric components may be incorporated in the material 211. Furthermore, a place-holder material 212, such as a polysilicon material, a silicon/germanium material and the like, may be formed above the material 211, wherein, in some cases (not shown), a further conductive cap material may be provided between the material 212 and the dielectric material 211, in particular when the material 211 may comprise a high-k dielectric layer. As previously indicated, a length of the gate electrode structures 210A, 210B, i.e., in FIG. 2a, the horizontal extension of the placeholder material 212 in the vicinity of the dielectric material 211, may be 50 nm and less, such as 40 nm and less, in sophisticated semiconductor devices. It should be appreciated, however, that the principles disclosed herein may not be restricted to any specific length of the gate electrode structures 210A, 210B, unless such restrictions are explicitly set forth in some of the embodiments or in the appended claims.

Moreover, the gate electrode structures 210A, 210B may comprise a dielectric cap material 213, for instance comprised of silicon nitride, silicon dioxide and the like, wherein, in some illustrative embodiments, the cap layer 213 may be comprised of a dielectric base material, which may be referred to as a silicon nitride material and which may thus be comprised of substantially silicon and nitrogen. Furthermore, sidewall spacer elements 214, 215 may be provided, for instance in the form of silicon nitride spacers and the like. Furthermore, in the manufacturing stage shown, the gate electrode structures 210A, 210B are embedded in an interlayer dielectric material 261 of a contact level 260. The interlayer dielectric material 261 may be considered as a uniform material in the sense that the material composition may be substantially the same so that, in the embodiment shown, any further separate material layers of different material composition may not be provided in the contact level 260. In some illustrative embodiments, the interlayer dielectric material 261 may be comprised of the same dielectric base material as the dielectric cap layer 213 and, in some illustrative embodiments, as the spacer structure 215 and possibly the spacer structure 214. For example, when the components 213, 215 and 214, or at least essential portions thereof, are comprised of silicon nitride, also the interlayer dielectric material 261 may be formed on the basis of a silicon nitride material. In other illustrative embodiments, the components 213, 214, 215 may be formed on the basis of a silicon dioxide material and, in this case, also the interlayer dielectric material 261 may be provided on the basis of a silicon dioxide material.

In the embodiment shown in FIG. 2a, the interlayer dielectric material 261 may be formed directly on the semiconductor layer 202 and thus on any contact areas of the transistors 250A, 250B, such as metal silicide regions (not shown), when already provided in this manufacturing stage. In other illustrative embodiments, as will be described later on with reference to FIG. 2e, an appropriate etch stop material may be provided, however, with a reduced thickness compared to conventional strategies.

The semiconductor device 200 as illustrated in FIG. 2a may be formed on the basis of any appropriate process strategy for forming the transistors 250A, 250B comprising the gate electrode structures 210A, 210B as illustrated in FIG. 2a. For example, similar process techniques may be applied, as previously discussed with reference to the semiconductor device 100, when referring to the transistors 150A, 150B. After completing the basic configuration of the transistors 250A, 250B, the interlayer dielectric material 261 may be deposited, which may be accomplished on the basis of a substantially non-conformal deposition technique, which may have a superior fill behavior, even if closely spaced gate electrode structures are considered, such as the gate electrode structures 210A, 210B. For example, silicon dioxide may be deposited on the basis of sub-atmospheric CVD, high density plasma CVD and the like, thereby providing superior gap fill capabilities. Similarly, silicon nitride material may be deposited on the basis of appropriate deposition parameters in order to obtain a bottom-to-top fill behavior, wherein appropriate process parameters may be readily established on the basis of well-known recipes known from sub-atmospheric deposition techniques and high density plasma deposition strategies. Thus, starting from any such well-established process techniques, appropriate parameter settings may be obtained for the specific configuration of the semiconductor device 200, for instance in terms of internal stress level, material composition, critical dimensions and the like. It should be appreciated that, due to the omission of any further separate dielectric layer or by providing a very thin etch stop layer, as will be described later on, the device topography caused by the gate electrode structures 210A, 210B may no longer be increased by providing any conformal material layers and thus the resulting surface topography of the material 261 may be less pronounced compared to conventional strategies, as previously described with reference to the device 100.

FIG. 2b schematically illustrates the semiconductor device 200 during a removal process 205 which, in some illustrative embodiments, may comprise a chemical mechanical planarization process. During the process 205, the interlayer dielectric material 261 may be planarized and may be reduced in thickness so as to finally expose the dielectric cap layers 213 (FIG. 2a) and the spacer structures 214, 215. Due to the similarity of the material composition of these components compared to the interlayer dielectric material 261, a significantly simplified process control may be established since any material may be removed with a very similar removal rate. Consequently, due to previously reduced surface topography of the material 261 and due to the similarity of the materials in the components 213, 215 and 214, a pronounced degree of dishing may be avoided or at least significantly reduced compared to the conventional process strategy. Consequently, during the further advance of the removal process 205, the cap materials 213 of any transistor type may be removed more efficiently and on the basis of a superior process uniformity, thereby significantly reducing any overpolish times required to reliably expose or form a surface 212S of the placeholder material 212. For example, in a final phase of the removal process 205, increasingly the material 212 may be exposed, wherein, however, contrary to the conventional approaches, the material 261 may be provided laterally adjacent to the gate electrode structures 210A, 210B and may have substantially the same removal rate, as for instance the spacer structure 215 and the cap layer 213, thereby avoiding any undesired recessing of the material 261, in particular in the vicinity of the gate electrode structures 210A, 210B. It is to be noted that even different materials may be used for the components 213, 214 and 215, as long as these components may be comprised of a material having a higher removal rate since, in this case, any pronounced degree of dishing may occur within the corresponding gate electrode structures, thereby not contributing to pronounced leakage current paths. For example, the dielectric cap layer 213 and/or the spacer structures 214, 215 may comprise a silicon dioxide material, which may have a greater removal rate during the process 205, which may be configured to remove silicon nitride material with a desired well-controllable removal rate. In this case, the material 212 may be efficiently exposed without causing any undue dishing effects in the material 261.

Similarly, in other illustrative embodiments, the material 261 may be comprised of silicon dioxide and in this case also the components 213, 214 and 215 may be provided on the basis of a silicon dioxide material, thereby also enabling superior process uniformity during the removal process 205.

FIG. 2c schematically illustrates the semiconductor device 200 in a further advanced manufacturing stage. As illustrated, the gate electrode structures 210A, 210B may comprise a material system 216, which may comprise a highly conductive electrode metal, such as aluminum and the like, possibly in combination with any other material or material system in order to adjust an appropriate work function and thus threshold voltage of the transistors 250A, 250B. For example, a fill or core metal 216A may be provided, for instance, in the form of aluminum, possibly in combination with one or more layers 216B comprising appropriate metal species, such as lanthanum, aluminum and the like, as required for adjusting the threshold voltage. In other cases, the material layer 216B may comprise a high-k dielectric material which may be provided in combination with a conventional dielectric material, which may have been preserved during the previous processing, while, in other cases, any dielectric material may be removed from the gate electrode structures 210A, 210B and may be replaced by a high-k dielectric material, possibly in combination with a conventional dielectric material. To this end, any appropriate process sequence may be applied in which the placeholder material 212 of FIG. 2b may be removed by using any well-established wet chemical etch recipes, plasma assisted etch processes, wherein, if required, also any underlying materials may be removed, or at least may be reduced in thickness. Thereafter, a high-k dielectric material may be deposited, if required, followed by the deposition of one or more metal-containing electrode materials based on sputter deposition, CVD, electrochemical deposition and the like. Thereafter, any excess material may be removed, for instance by CMP, wherein the superior surface topography, i.e., the substantially non-recessed configuration of the interlayer dielectric material 261 may also provide superior efficiency with respect to removing any undue metal residues.

FIG. 2d schematically illustrates the semiconductor device 200 in a further advanced manufacturing stage. As illustrated, a contact element 263 may be formed in the contact level 260, i.e., in the interlayer dielectric material 261, so as to connect to a contact region 254, such as a metal silicide material and the like. The contact element 263 may be formed on the basis of lithography techniques in which an appropriate etch mask may be provided to define the lateral size and position of the contact element 263. Thereafter, an etch process may be performed to etch through the material 261 wherein, contrary to conventional approaches, a single material system may have to be etched, thereby enhancing overall process control and thus uniformity of the corresponding contact openings provided in the material 261. It should be appreciated that the contact region 254 may be formed by locally forming a metal silicide through the corresponding contact opening, while, in other cases, as previously explained, metal silicide may be formed prior to depositing the interlayer dielectric material 261. Thereafter, an appropriate contact material, such as tungsten, aluminum, copper and the like, possibly in combination with appropriate barrier materials, may be deposited on the basis of any appropriate deposition technique, followed by the removal of any excess material, for instance by performing a CMP process. Also in this case, a reduced degree of recessing in the material 261 may enable significantly reduced overpolish times, thereby preserving a desired gate height while nevertheless reliably forming the gate electrode structures 210A, 210M and the contact element 263 as electrically insulated components.

FIG. 2e schematically illustrates the semiconductor device 200 according to further illustrative embodiments. As illustrated, an etch stop layer 262 may be formed below the interlayer dielectric material 261, wherein, in one illustrative embodiment, the layer 262 may be comprised of silicon dioxide, while the interlayer dielectric material 261 may be comprised of silicon nitride. The etch stop layer 262 may be provided with a reduced thickness of, for instance, 10 nm or less, while, in some illustrative embodiments, a thickness of 5 nm and less may be used. Consequently, the presence of the etch stop material of the layer 262 may not unduly affect the removal process of FIG. 2b, since a corresponding reduced thickness may be efficiently removed, in particular when the material of the layer 262 may have a greater removal rate compared to the interlayer dielectric material 261. For example, for a given slurry material and given process parameters, a desired removal rate for silicon nitride material may be accomplished during the process 205 of FIG. 2b, as discussed above, wherein the removal rate of silicon dioxide may be greater, and thus any non-uniformity outside of the gate electrode structures 210A, 210B may be avoided. On the other hand, highly selective plasma assisted etch recipes are available for etching silicon nitride material selectively with respect to silicon dioxide so that the reduced thickness, indicated by 262T, may provide sufficient etch stop capabilities in order to reliably stop a corresponding etch process in order to form a contact opening 263A within the material 261. Moreover, by providing the etch stop layer 262, a certain degree of misalignment of the contact opening 263A may be tolerated, since the contact opening 263A may be restricted to an area laterally enclosed by the etch stop layer 262. Consequently, the contact opening 263A may be provided with superior reliability and with a superior robustness in terms of any misalignments, thereby also contributing to increased production yield and performance of the semiconductor device 200. After forming the contact opening 263A, the etch stop layer 262 may be opened on the basis of any appropriate etch process, such as a wet chemical etch process and the like. Thereafter, the further processing may be continued, as is also described above.

As a result, the present disclosure provides semiconductor devices and manufacturing techniques in which an interlayer dielectric material may be provided with a substantially uniform thickness and a substantially uniform height level between closely spaced gate electrode structures, which may be accomplished by simplifying the material system that has to be removed above the gate electrode structures upon exposing a placeholder material therein. For example, an interlayer dielectric material having similar removal behavior as any dielectric cap materials and spacer materials in the gate electrode structures may be provided on the basis of a non-conformal deposition process, possibly in combination with a very thin etch stop material. Consequently, a pronounced recessing or dishing of the interlayer dielectric material between the gate electrode structures may be avoided or at least significantly reduced compared to conventional strategy, thereby reducing yield losses and contributing to superior performance and reliability of the transistor elements comprising sophisticated high-k metal gate electrode structures.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a dielectric layer above a gate electrode structure of a transistor, said gate electrode structure comprising a placeholder material and a dielectric cap layer formed above said placeholder material, said dielectric cap layer and said dielectric layer comprising a common dielectric base material;
removing said dielectric cap layer and a portion of said dielectric layer so as to expose a surface of said placeholder material; and
replacing said placeholder material at least with a metal-containing electrode material.

2. The method of claim 1, wherein forming said dielectric layer comprises depositing said dielectric base material by performing a non-conformal deposition process.

3. The method of claim 1, wherein said dielectric base material comprises silicon nitride.

4. The method of claim 1, wherein said dielectric base material comprises silicon dioxide.

5. The method of claim 1, wherein removing said dielectric cap layer and a portion of said dielectric layer comprises performing a chemical mechanical planarization process so as to commonly remove material of said dielectric cap layer and said dielectric layer at least in a final phase of said chemical mechanical planarization process.

6. The method of claim 1, further comprising forming a contact opening in said dielectric layer so as to extend to a contact region formed in an active region of said transistor, wherein said contact region is used as an etch stop material.

7. The method of claim 1, further comprising forming an etch stop layer above said gate electrode structure prior to forming said dielectric layer.

8. The method of claim 7, wherein said etch stop layer is formed with a thickness of approximately 10 nm or less.

9. The method of claim 7, further comprising forming a contact opening in said dielectric layer and using said etch stop layer as an etch stop.

10. The method of claim 1, further comprising forming a spacer structure on sidewalls of said gate electrode structure, wherein said spacer structure comprises spacer elements comprised of said dielectric base material.

11. A method, comprising:
forming a silicon nitride-containing dielectric material above and laterally adjacent to a gate electrode structure of a transistor by performing a non-conformal deposition process, said gate electrode structure comprising a placeholder material;
forming an exposed top surface of said placeholder material by removing a portion of said dielectric material; and
replacing said placeholder material with at least a metal-containing electrode material.

12. The method of claim 11, further comprising forming a dielectric cap layer above said placeholder material and removing said dielectric cap layer when forming said exposed top surface.

13. The method of claim 12, wherein said dielectric cap layer is formed by using at least one of silicon nitride and silicon dioxide.

14. The method of claim 13, wherein forming said exposed surface of said placeholder material comprises performing a chemical mechanical planarization process.

15. The method of claim 11, further comprising forming a contact opening in said dielectric layer so as to connect to a contact region of said transistor and using said contact region as an etch stop material.

16. The method of claim 11, further comprising forming an etch stop layer above said gate electrode structure prior to forming said dielectric material, wherein said etch stop layer has a thickness of approximately 10 nm or less.

17. The method of claim 11, further comprising forming a spacer structure on sidewalls of said gate electrode structure by forming one or more spacer elements on the basis of a silicon nitride material.

18. A semiconductor device, comprising:
a first high-k metal gate electrode structure and a second high-k metal gate electrode structure comprising a metal gate electrode material; and
an interlayer dielectric material formed laterally between said first and second high-k metal gate electrode structures and having a substantially uniform thickness and a substantially constant height level between said spacer structures of said first and second gate electrode structures.

19. The semiconductor device of claim 18, wherein said interlayer dielectric material is comprised of silicon nitride.

20. The semiconductor device of claim 19, further comprising an etch stop layer formed below said interlayer dielectric material and having a thickness of approximately 10 nm or less.
